(19) United States
(12) Patent Application Publication
(10) Pub. No.: US 2022/0359826 A1
(43) Pub. Date: Nov. 10, 2022

(54) FORMULATION COMPRISING A P-TYPE ORGANIC SEMICONDUCTOR MATERIAL AND AN N-TYPE SEMICONDUCTOR MATERIAL

(71) Applicant: ISORG, Limoges CEDEX 3 (FR)

(72) Inventors: Alex LHEUREUX, GRENOBLE (FR); Emeline SARACCO, GRENOBLE (FR); Benjamin BOUTHINON, GRENOBLE (FR)

(21) Appl. No.: 17/622,618

(22) PCT Filed: Jun. 22, 2020
(86) PCT No.: PCT/EP2020/067379

§ 371 Date: Dec. 23, 2021

(30) Foreign Application Priority Data
Jun. 24, 2019 (FR) FR1906821

(51) Int. Cl. H01L 51/00

(52) U.S. Cl. CPC H01L 51/0036; H01L 51/0047; H01L 51/4253

(57) ABSTRACT

A formulation for preparing organic electronic devices, has: a p-type organic semiconductor polymer including a conjugated aryl polymer, a conjugated heteroaryl compound or a mixture of at least two of these compounds; an n-type semiconductor material including fullerene, substituted fullerene, or a mixture of at least two of these compounds; and a non-aqueous solvent. The concentration of the p-type organic semiconductor polymer is in the range from 8 mg/mL to 12 mg/mL per milliliter of solvent and the concentration of the p-type organic semiconductor material is in the range from 18 mg/mL to 22 mg/mL per milliliter of solvent.

### RELATED APPLICATIONS

The present patent application claims the priority benefit of French patent application FR19/06821, which is herein incorporated by reference.

### FIELD

The present disclosure generally relates to formulations comprising an organic semiconductor (OSC) as well as to inks for the preparation of organic electronic devices, as well as to methods of preparation of organic electronic devices using such formulations.

### BACKGROUND

During the last decades, organic semiconductors (OSC) have aroused a strong academic and industrial interest. Examples of applications where organic semiconductors have already been used are organic photodiodes (OPDs), such as, for example, for optical sensors, organic light-emitting diodes (OLEDs), for example, for displays and lighting, and organic photovoltaic cells (OPVs).

Although the deposition of inorganic semiconductors generally requires vacuum technologies, organic semiconductors may be applied by relatively simple and inexpensive deposition and coating methods, particularly spin coating methods or spreading methods.

The inks and formulations to be applied by such methods generally require a viscosity specific to the implemented method. The adjustment of the viscosity of the ink is complicated by the fact that it depends on a number of variables, such as the nature of the ink components, for example, the molecular weight of the organic semiconductor component or the nature of the solvent, as well as the respective concentrations of the components. Further, organic semiconductor components are frequently designed to maximize their electronic properties, such as for example the mobility of charge carriers, without taking into account the solubility, thus limiting the choice of potential solvents.

### SUMMARY

Thus, an object of an embodiment is to at least partly overcome the previously-described disadvantages of inks comprising a semiconductor organic compound.

An object of an embodiment is for the viscosity of the ink to be adapted to the implemented deposition method.

An embodiment provides a formulation comprising:
a p-type organic semiconductor polymer comprising a conjugated aryl compound, a conjugated heteroaryl compound, or a mixture of at least two of these compounds;
an n-type semiconductor material comprising fullerene, substituted fullerene, or a mixture of at least two of these compounds; and
a non-aqueous solvent, the concentration of the p-type organic semiconductor polymer being in the range from 8 mg/mL to 12 mg/mL per milliliter of solvent and the concentration of the n-type organic semiconductor material being in the range from 18 mg/mL to 22 mg/mL per milliliter of solvent.

According to an embodiment, the solvent comprises toluene, o-xylene, m-xylene, or p-xylene, trimethylbenzene, tetralin, anisole, alkylanisoles, naphtalene, tetrahydronaphtalene, alkylnaphtalene, or a mixture of at least two of these solvents.

According to an embodiment, the formulation has a viscosity in the range from 8 mPa·s to 12 mPa·s.

According to an embodiment, the p-type semiconductor polymer comprises aryl groups and thiophene groups.

According to an embodiment, the n-type semiconductor material is PCBM-C₆₀.

According to an embodiment, the solvent is tetrahydronaphthalene.

An embodiment also provides a use of a formulation such as previously defined, such as a coating or printing ink for the preparation of optoelectronic devices.

An embodiment also provides a method of preparing a formulation such as previously defined, comprising mixing the p-type organic semiconductor polymer and the n-type semiconductor material in the form of powders, adding the non-aqueous solvent to the mixture to obtain the formulation, heating the formulation, and filtering the formulation.

According to an embodiment, the p-type organic semiconductor polymer has a targeted molecular weight and is obtained by mixing a first powder of the polymer having a first molecular weight greater than the targeted molecular weight and a second powder of the same polymer having a second molecular weight smaller than the targeted molecular weight.

According to an embodiment, the step of heating the formulation comprises heating the formulation from 30 min to 2 hrs at a temperature in the range from 50° C. to 70° C.

According to an embodiment, the filtering step is implemented by having the formulation pass through a filter having a pore size in the range from 0.2 μm to 1 μm.

An embodiment also provides an optoelectronic device prepared from a formulation such as previously defined.

According to an embodiment, the optoelectronic device is selected from organic photodiodes, organic light-emitting photodiodes, and organic photovoltaic cells.

### BRIEF DESCRIPTION OF THE DRAWINGS

The foregoing features and advantages, as well as others, will be described in detail in the following description of specific embodiments given by way of illustration and not limitation with reference to the accompanying drawings, in which:

FIG. 1 shows, in the form of a block diagram, an embodiment of a method of manufacturing a semiconductor layer comprising a p-type organic semiconductor material and an n-type semiconductor material; and

FIG. 2 is a partial simplified cross-section view of an embodiment of an optical sensor.

### DESCRIPTION OF THE EMBODIMENTS

Like features have been designated by like references in the various figures. In particular, the structural and/or functional features that are common among the various embodiments may have the same references and may dispose identical structural, dimensional and material properties. For the sake of clarity, only the steps and elements that are useful for an understanding of the embodiments described herein have been illustrated and described in detail. Unless specified otherwise, the expressions “around”, “approximately”, “substantially” and “in the order of” signify within 10%, and preferably within 5%.

In the present application, the terms “ink” and “formulation” are used to designate a composition comprising at least one p-type organic semiconductor material, one n-type semiconductor material, and at least one solvent. In the context of the present application, the term “organic semiconductor material” is used to designate a semiconductor material comprising at least one organic semiconductor material. Accordingly, such an organic semiconductor material may also comprise one or a plurality of inorganic semiconductor compounds.

Unless otherwise indicated, the molecular weight is given in number-average molecular weight Mn or weight-average molecular weight Mw, and is determined by gel permeation chromatography (GCP) with respect to a standard polystyrene in eluents such as tetrahydrofuran, trichloromethane, chlorobenzene, or 1,2,4-trichlorobenzene. Unless otherwise indicated, chlorobenzene is used as a solvent for the measurements. The molecular weight distribution (“MWD”), which may also be called polydispersity index (“PDI”), of a polymer is defined as ratio Mw/Mn. The term degree of polymerization, also called total number of repeated units, m, designates the average degree of polymerization indicated as m=Mn/MU, where Mn is the number-average molecular weight of the polymer and MU is the molecular weight of the repetition unit, see J. M. G. Cowie, Polymers: Chemistry & Physics of Modern Materials, Blackie, Glasgow, 1991.

In the following description, the expression “repeat unit” or “repeating unit” designates a monomer unit forming the backbone of the polymer compound and is a structural unit, one of which at least is present in the polymer compound. The expression “n-valent heterocyclic group” (where n is equal to 1 or 2), designates a group which is prepared by removing n hydrogen atom(s) from a heterocyclic compound (in particular, an aromatic heterocyclic compound) and where these fractions form bonds with other atoms. The expression “heterocyclic compound” designates an organic compound having a cyclic structure, which contains in the cycle, not only carbon atoms, but also a hetereoatom such as an oxygen atom, a sulfur atom, a nitrogen atom, a phosphorus atom, or a boron atom among the elements forming the cycle.

According to an embodiment, the formulation according to the present application comprises:
a) at least one n-type organic semiconductor material and at least one p-type organic semiconductor material;
b) at least one solvent;
c) possibly at least one polymer in the form of particles; and
d) possibly at least one conductive additive.

p-Type Organic Semiconductor Material

The formulation may comprise one or a plurality of p-type organic semiconductor compounds and one or a plurality of n-type semiconductor compounds. The semiconductor compounds, preferably p-type organic semiconductor compounds, may for example also be one or a plurality of photoactive compounds. The term “photoactive compound” is used to designate a compound which helps converting the incoming light into electric power.

The p-type organic semiconductor compound(s) may be a polymer, an oligomer, or a small molecule, and may be represented by the following formula (I):

-[M-]ₘ- (I)

where M is such as defined hereafter and, for the purposes of the present disclosure, m is 1 for a small molecule, between 2, and 10 for an oligomer, and at least 11 for a polymer. Preferably, the p-type organic semiconductor compounds each are a polymer.

Examples of adapted p-type organic semiconductor compounds all comprise conjugated aryl and heteroaryl compounds, possibly further comprising one or a plurality of ethene-2,1-diyl (*—(R¹)C═C(R²)—*) and ethynediyl (*—C≡C— *) groups, R¹ and R² being such as defined hereafter.

Groups R¹ and R² are carbyl groups, preferably selected from the group formed by alkyl groups having from 1 to 20 carbon atoms, partially or totally fluorinated alkyl groups having from 1 to 20 carbon atoms, phenyl groups and phenyl groups substituted with alkyl groups having from 1 to 20 carbon atoms or partially or totally fluorinated alkyl groups having from 1 to 20 carbon atoms.

Examples of p-type organic semiconductor compounds may be conjugated aryl and heteroaryl compounds, for example, an aromatic compound, preferably containing two or more, and more preferably at least three, aromatic cycles. Preferred examples of p-type organic semiconductor compounds comprise aromatic cycles selected from 5-, 6-, or 7-membered aromatic cycles, more preferably selected from 5- or 6-membered aromatic cycles.

Each of the aromatic cycles of the p-type organic semiconductor compound may possibly contain one or a plurality of heteroatoms selected from among Se, Te, P, Si, B, As, N, O, or S, generally from among N, O, or S.

Further, the aromatic cycles may possibly be substituted with alkyl, alkoxy, polyalcoxy, thioalkyl, acyl, aryl, or substituted aryl groups, a halogen group, particularly fluorine, cyano, nitro, or a secondary or tertiary alkylamine or arylamine, possibly substituted, represented by —N(R³) (R⁴), where R³ and R⁴ are each independently H, a possibly substituted alkyl, aryl, alcoxy group or a possibly substituted polyalcoxy group. Further, when R³ and R⁴ are an alkyl or aryl group, they may be possibly fluorinated.

The above-mentioned aromatic cycles may be condensed or linked to a conjugated linking group such as —C(T₁)═C(T₂)—, —C≡C—, —N(R′″)—, —N═N—, (R′″)═N—, N═C(R′″)⁻, where T₁ and T₂ each independently represent H, Cl, F, —CN or lower alkyl groups such as alkyl groups having from 1 to 4 carbon atoms, R′″ representing H, a possibly substituted alkyl group, or a possibly substituted aryl group. Further, when R′″ is an alkyl or aryl group, it may be fluorinated.

Preferred examples of p-type organic semiconductors adapted for the present application comprise compounds, oligomers, and derivatives of compounds selected from the group formed of conjugated hydrocarbon polymers such as polyacenes, polyphenyl, poly(phenylene vinylene), polyfluorene, including oligomers of such conjugated hydrocarbon polymers; condensed aromatic hydrocarbons, such as tetracene, chrysene, pentacene, pyrene, perylene, coronene, or their soluble substituted derivatives; phenylenes para-substituted with oligomers such as p-quaterphenyl (p-4P), p-quinquephenyl (p-5P), p-sexiphenyl (p-6P), or their soluble substituted derivatives; conjugated heterocyclic polymers such as 3-substituted poly(thiophenes), 3,4-disubstituted poly(thiophenes), possibly substituted polythieno[2,3-b]thiophene, possibly substituted polythieno[3,2-b]thiophene, 3-substituted poly(selenophenes), polybenzothiophene, polyisothianaphtene, N-substituted poly(pyrrole), 3-substituted poly(pyrrole 3), 3,4-disubstituted poly(pyrrole), polyfuran, polypyridine, poly-1,3,4-oxadiazoles, polyisothianaphthene, N-substituted poly(anilin), 2-substituted poly(anilin), 3-substituted poly(anilin), 2,3-disubstituted poly(anilin), polyazulene, polypyrene; pyrazolin compounds; polyselenophene; polybenzofuran; polyindole; polypyridazine; benzidine compounds; stilbene compounds; triazines; porphines, phtalocyanines, fluorophtalocyanines, naphtalocyanines, or metal-free or metal containing substituted fluoronaphtalocyanines; N,N′-dialkyl, substituted dialkyl, diaryl or substituted diaryl, 1,4,5,8-naphthalenetetracarboxylic diimide and fluorinated derivatives; N, N′-dialkyl, substituted dialkyl, diaryl or substituted diaryl, 3,4,9,10-perylenetetracarboxylic diimide; bathophenanthroline; diphenoquinones; 1,3,4-oxadiazoles; 11,11,12,12-tetracyanonaptho-2,6-quinodimethane; α,α′-bis (dithieno [3,2-b-2 ‘, 3T-d] thiophene); 2,8-dialkyl, substituted dialkyl, diaryl or substituted diaryl anthradithiophene; 2,2’-bisbenzo [1,2-b: 4,5-b′] dithiophene.

Further, in certain preferred embodiments according to the present invention, the p-type organic semiconductor compounds are polymers or copolymers which comprise one or a plurality of repeat units selected from among thiophene-2,5-diyl, 3-substituted thiophene-2,5-diyl, possibly substituted thieno[2,3-b]thiophene-2,5-diyl, possibly substituted thieno[3,2-b]thiophene-2,5-diyl, selenophene-2,5-diyl or 3-substituted selenophene-2,5-diyl.

Other preferred examples of p-type organic semiconductor components are copolymers comprising one or a plurality of electron acceptor units and one or a plurality of electron donor units. The preferred copolymers of this preferred embodiment are for example copolymers comprising one or a plurality of benzo [1,2-b:4,5-b′]dithiophene-2,5-diyl units, possibly 4,8-di-substituted, and further comprising one or a plurality of aryl or heteroaryl units selected form group A and group B, preferably comprising at least one group-A unit and at least one group-B unit, group A being formed of the aryl or heteroaryl groups having electron donor properties and group B being formed of the aryl or heteroaryl groups having electron acceptor properties.

Group A is formed of selenophene-2,5-diyl, thiophene-2,5-diyl, thieno[3,2-b]thiophene-2,5-diyl, thieno[2,3-b]thiophene-2,5-diyl, selenopheno[3,2-b] selenophene-2,5-diyl, selenopheno[2,3-b]selenophene-2,5-diyl, selenopheno[3,2-b]thiophene-2,5-diyl, selenopheno[2,3-b]thiophene-2,5-diyl, benzo[1,2-b:4,5-b′] dithiophene-2,6-diyle, 2,2-dithiophene, 2,2-diselenophene, dithieno [3,2-b:2′, 3′-d]silol-5,5-diyl, 4H-cyclopenta [2,1-b:3,4-b′] dithiophene-2,6-diyl, 2,7-di-thien-2-yl-carbazole, 2,7-di-thien-2-yl-fluorene, indaceno [1,2-b:5,6-b′] dithiophene-2,7-diyl, benzo [1″, 2″:4,5;4″, 5″:4′,5′]bis (silolo [3,2-b:3′, 2′-b′] thiophene)-2,7-diyl, 2,7-di-thien-2-yl-indaceno [1,2-b:5,6-b′] dithiophene, 2,7-di-thien-2-yl-benzo [1″, 2″: 4, 5; 4″, 5″: 4′, 5′] bis (silolo [3,2-b: 3′, 2′-b′] thiophene)-2,7-diyl, and 2,7-di-thien-2-yl-phenanthro [1,10,9,8-c, d, e, f, g] carbazole, possibly substituted with one or a plurality of, preferably one or two, groups R¹ such as previously defined.

Group B is formed of benzo [2,1,3] thiadiazole-4,7-diyl, 5,6-dialkyl-benzo [2,1,3] thiadiazole-4,7-diyl, 5,6-dialkoxybenzo [2, 1,3] thiadiazole-4,7-diyl, benzo [2,1,3] selenadiazole-4,7-diyl, 5,6-dialcoxy-benzo [2,1,3] selenadiazole-4,7-diyl, benzo [1,2,5] thiadiazole-4,7, diyl, benzo [1,2,5] selenadiazole-4,7, diyl, benzo [2,1,3] oxadiazole-4,7-diyl, 5, 6-dialkoxybenzo [2,1,3] oxadiazole-4,7-diyl, 2H-benzotriazole-4,7-diyl, 2,3-dicyano-1,4-phenylene, 2,5-dicyano, 1,4-phenylene, 2,3-difluoro-1,4-phenylene, 2,5-difluoro-1,4-phenylene, 2,3,5,6-tetrafluoro-1,4-phenylene, 3,4-difluorothiophene-2, 5-diyl, thieno [3,4-b] pyrazine-2,5-diy, quinoxaline-5,8-diyl, thieno [3,4-b] thiophene-4,6-diyl, thieno [3,4-b] thiophene-6,4-diyl, and 3,6-pyrrolo [3,4-c] pyrrole-1,4-dione, all possibly substituted with one or a plurality of, preferably, one or two, groups R¹ such as previously defined.

In other preferred embodiments of the present invention, the p-type organic semiconductor compounds are substituted oligoacenes. Examples of such oligoacenes may for example be selected from the group formed of pentacene, tetracene, or anthracene, and of their heterocyclic derivatives. Bis (trialkylsilylethynyl) oligoacenes or bis (trialkylsilylethynyl) heteroacenes, such as for example described in patents or patent application U.S. Pat. No. 6,690,029, WO 2005° 055248 A1, or U.S. Pat. No. 7,385,221 may also be used.

n-Type Semiconductor Material

Examples of adapted n-type semiconductor compounds are well known by those skilled in the art and comprise inorganic compounds and organic compounds.

The n-type semiconductor compound may for example be an inorganic semiconductor compound selected from the group comprising zinc oxide (ZnOₓ), zinc tin oxide (ZTO), titanium oxide (TiOₓ), molybdenum oxide (MoOₓ), nickel oxide (NiOₓ), cadmium selenide (CdSe), and mixtures of at least two of these compounds.

The n-type semiconductor compound may for example selected from the group comprising graphene, fullerene, substituted fullerene, and any mixture of at least two of these compounds.

Examples of adapted fullerenes and substituted fullerenes may be selected from the group comprising indene-C₆₀-bisadduct such as ICBA, or methano-C₆₀ fullerene derived from the methylic ester of (6,6)-phenyl-butyric acid, also known as “PCBM-C₆₀” or “C₆₀PCBM”, as described, for example, in G. Yu, J. Gao, J C Hummelen, F. Wudl, A J Heeger, Science 1995, vol. 270, p. 1789 and the following, or structural compounds analogous for example to a C₆₁ fullerene group, a C₇₀ fullerene group, or a C₇₁ fullerene group or an organic polymer (see for example Coakley, K. M. and McGehee, M. D. Chem. Mater. 2004, 16, 4533).

Other examples of n-type semiconductor components are described in Zhang et al's publication entitled “Nonfullerene Acceptor Molecules for Bulk Heterojunction Organic Solar Cells” (Chemical Reviews, 2018 Apr. 11; 118(7):3447-3507. doi: 10.1021/acs.chemrev.7b00535. Epub 2018 Mar. 20).

Preferably, the p-type organic semiconductor compound is mixed with an n-type semiconductor such as a fullerene or a substituted fullerene, such as for example PCBM-C₆₀, PCBM-C₇₀, PCBM-C₆₁, PCBM-C₇₁, bis-PCBM-C₆₁, bis-PCBM-C₇₁, ICMA-C₆₀ (1%4′-dihydronaphto[2%3′:1,2][5,6]fullerene-C₆₀), ICBA-C₆₀, oQDM-C₆₀ (1%4′-dihydronaphto[2′,3′:1,9][5,6] fullerene-C₆₀-1h), bis-oQDM-C₆₀, graphene, or a metal oxide, such as for example ZnO, TiO, ZTO, MoO, NiOₓ or quantum dots for example made of PbS, CdSe, or CdS, to form the active layer in an OPV or OPD device.

Polymer in Particle Form

According to an embodiment, the present formulation comprises polymer particles, said polymer particles having at diameter of at most 2 μm. Preferably, said polymer particles have a diameter of at most 1.5 μm, more preferably of at most 1.0 μm, or 0.9 μm, or 0.8 μm, or 0.7 μm, or 0.6 μm, and more preferably still of at most 0.5 μm. Preferably, said polymer particles have a diameter of at least 10 nm, more preferably of at least 15 nm, and more preferably still of at least 20 nm.

Preferably, said polymer particles comprise a polymer which exhibits a crosslinking, that is, a polymer with a degree of crosslinking.

The polymer is capable of forming a stable dispersion. In context of the present application, the term “stable dispersion of polymer particles” designates a dispersion of polymer particles in the solvent(s) such as define hereabove, said polymer particles remaining dispersed for at least 24 hours, preferably for at least 48 hours after having been dispersed in the solvent(s).

The polymer particles preferably comprise at least 50 wt. %, or 60 wt. %, or 70 wt. %, or 80 wt. %, or 90 wt. %, or 95 wt. %, or 97 wt. %, or 99 wt. % of a crosslinkable polymer with respect to the total weight of the polymer particles, or preferably are such a crosslinkable polymer.

Examples of crosslinkable polymers capable of being used in the present application may for example be selected from the group formed of polystyrene, of polyacrylic acid, of polytethacrylic acid, of poly(methyl methacrylate), of epoxy resins, of polyesters, of vinyl polymers, or of any mixture of at least two of these compounds, among which polystyrene and polyacrylic acid are preferred, and polystyrene is preferred above all.

Crosslinkable or already crosslinked polymers are generally known by those skilled in the art and may be obtained by commercial sources, such as for example, Spherotech Inc., Lake Forest, Ill., USA or Sigma-Aldrich.

Preferably, the polymer comprised in the polymer particles has a number-average molecular weight Mn (such as determined, for example, by GPC) of at least 50,000 g/mol, preferably of at least 100,000 g/mol, more preferably of at least 150,000 g/mol, and more preferably still of at least 200,000 g/mol. Preferably, the polymer comprised in the polymer particles has a number-average molecular weight Mn (such as determined, for example, by GPC) of at most 2,000,000 g/mol, preferably of at most 1,500,000 g/mol, and more preferably of at most 1,000,000 g/mol.

Preferably, the polymer particles of the present invention are not soluble in the solvents contained in the present formulation.

Conductive Additive

According to an embodiment, the formulation further comprises at least one conductive additive selected from the group comprising volatile compounds or compounds which are unable to chemically react with organic semiconductor materials (OSC). In particular, they are selected from compounds which have no permanent dopant effect on the OSC material (for example, by oxidizing or by chemically reacting with the OSC material), or from volatile compounds, or both. Accordingly, according to an embodiment, the formulation contains no additives, such as for example oxidizers or protonic or Lewis acids, which react with the OSC material by forming ion products. Further, according to an embodiment, the formulation contains no additives which are not volatile and which cannot be removed from the solid OSC material after treatment. If additives capable of electrically doping the OSC material, such as carboxylic acids are used, they should preferably be selected from among volatile components to be able to be removed from the OSC film after its deposition.

It may also be tolerated to add to the formulation conductive additives such as for example, oxidizers, Lewis acids, protic inorganic acids, or non-volatile protic carboxylic acids. However, the total concentration of these additives in the formulation should then preferably be smaller than 0.5%, more preferably smaller than 0.1%, more preferably still smaller than 0.01 wt. %. Preferably, however, the formulation contains no dopants selected from this group.

Thus, preferably, the conductive additives are selected not to permanently dope the OSC and/or they are removed from the OSC material after processing (where the treatment means for example comprise depositing the OSC material on a substrate or forming a layer or a film thereof) and/or they are present at a sufficiently low concentration to avoid a significant effect on the properties of the OSC material, for example caused by a permanent doping. In a still preferred manner, the conductive additives are not chemically bonded to the OSC material or to the film or to the layer comprising it.

The preferred conductive additives are selected from the group formed of compounds which do not oxidize the OSC material and which do not chemically react with the OSC material. The terms “oxidizing” and “chemically reacting” used hereabove and hereafter relate to a possible oxidation or other chemical reaction of the conductive additive with the OSC material in the conditions used for the manufacturing, the storage, the transport, and/or the use of the formulation and the OE device.

Other preferred conductive additives are selected from the group formed of volatile compounds. The term “volatile” such as used in the present description means that the additive may be removed from the OSC material by evaporation, after the OSC material has been deposited on an OE substrate or device, in conditions (such as temperature and/or a reduced pressure) which do not significantly damage the OSC material or the OE device. Preferably, this means that the additive has a boiling point or a sublimation temperature lower than 300° C., more preferably higher than 135° C., more preferably still higher than 120° C., at the pressure used, most preferably at the atmospheric pressure (1,013 hPa). The evaporation may also be accelerated, for example, by applying heat and/or a decreased pressure.

The adapted and preferred conductive additives which do not oxidize or do not chemically react with the OSC material are selected from the group formed of soluble organic salts, such as for example permanent quaternary ammonium or phosphonium salts, imidazolium, or other heterocyclic salts, where the anion is for example selected from the group formed of halogenides, sulfates, acetate formiate, tetrafluoroborate, hexafluorophosphate, methane sulfonate, triflate (trifluoromethane-sulfonate), bis(trifluoromethyl-sulfonyl) imide or others, and the cation is for example selected from the group of tetraalkyl ammonium, mixed tetraaryl ammonium or tetraalkylarylammonium ions, where the alkyl or aryl groups may be identical or different from one another, in addition to the heterocyclic ammonium salts (for example ionic liquids), protonated ammonium alkyl or aryl salts, or other nitrogen-based salts such as ammonium dilauryl salts. Other preferred conductive additives are selected from the group formed by salts of alkaline metals such as salts of bis(trifluoromethylsulfonyl) imide alkaline metals or inorganic salts.

The most preferred organic salts are for example tetra-n-butylammonium chloride, tetraoctylammonium bromide, benzyltridecylammonium benzene sulfate, diphenyl didodecylammonium hexafluorophosphate, N-methyl-N-trioctylammonium bis(trifluoromethylsulfonyl) imide, or a mixture or at least two of these compounds.

Volatile organic salts are more preferred. Adapted and preferred volatile organic salts are for example acetates, formiates, triflates, or ammonium methane sulfonates, such as trimethylammonium acetate, triethylammonium acetate, dihexylammonium methane sulfonate, octylammonium formiate, DBN (1,5-diazabicyclo[4.3.0]non-5-ene) acetate, or their mixtures or their precursors. A preferred additive of this type is for example a mixture of tributylamine and of trifluoroacetic acid, which provides the tributylammonium trifluoroacetate in the formulation, or a mixture of a short-chain trialkylamine (preferably with a boiling point lower than 200° C., more preferably lower than 135° C.) and a volatile organic acid (preferably with a boiling point higher than 200° C., more preferably higher than 135° C. and a pKa value equal to or greater than the pKa value of acetic acid).

Additional preferred conductive additives are alcohols, preferably volatile alcohols, volatile carboxylic acids, and organic amines, preferably volatile organic amines, more preferably alkylamines.

Adapted and preferred alcohols or volatile alcohols are for example isopropylic acids, isobutanol (2-butanol), hexanol, methanol, or ethanol.

Adapted and preferred volatile carboxylic acids are for example those having a boiling point lower than 135° C., more preferably lower than 120° C. (at the atmospheric pressure), such as for example formic acid, acetic acid, di- or trifluoroacetic acid. Other carboxylic acids, such as propionic or higher acids, di- or trichloroacetic acid, or methanesulfonic acid are also acceptable and may be used if their concentration is selected to be sufficiently low to avoid a significant doping of the OSC material, and is preferably greater than 0% and smaller than 0.5%, more preferably smaller than 0.25%, more preferably still smaller than 0.1% by weight.

Appropriate and preferred organic amines or volatile organic amines are alkylamines, for example, primary or secondary alkylamines, such as n-dibutylamine, ethanolamine, or octylamine.

In the case of conductive additives which are not removed from the OSC material after the deposition of the OSC layer, such as for example soluble organic salts or alcohols or non-volatile amines such as mentioned hereabove, some of these compounds may also have a permanent doping effect event if they do not oxidize or do not react with the OSC layer, for example, by trapping charges crossing the device. Accordingly, the concentration of these additives should be maintained sufficiently low for the device performance not to be substantially affected. The maximum tolerable concentration for each of the additives in the formulation may be selected according to its capacity of permanently doping the OSC material.

In the case of conductive additives selected from soluble organic salts, their concentration in the formulation is preferably from 1 ppm to 2 wt. %, more preferably from 50 ppm to 0.6 wt. %, more preferably still from 50 ppm to 0.1 wt. %.

In the case of conductive additives selected from volatile organic salts, their concentration in the formulation is preferably from 1 ppm to 2 wt. %, more preferably from 50 ppm to 0.6 wt. %, more preferably still from 50 ppm to 0.1 wt. %.

In the case of conductive additives selected from among alcohols or volatile alcohols, their concentration in the formulation from 1 wt. % to 20 wt. %, more preferably from 2 wt. % to 20 wt. %, more preferably still from 5 wt. % to 10 wt. %.

In the case of conductive additives selected from among volatile carboxylic acids, their concentration in the formulation is preferably of 0.001% or more, more preferably of 0.01% or more, and preferably of 2% or less, more preferably of 1% or less, more preferably still less than 0.5% (all percentages being by weight).

In the case of conductive additives selected from among amines and volatile amines, their concentration in the formulation is preferably of 0.001% or more, more preferably of 0.01% or more, and preferably of 2% or less, more preferably of 1% or less, more preferably still less than 0.5% (all percentages being by weight).

Conductive additives such as iodine and iodine compounds may also be used, such as for example IBr, iodine in the +3 oxidation state or other mild oxidizers capable of being removed from the solid OSC film, for example, by heating and/or under vacuum at drying step, to avoid doping the solid OSC film. However, such additives are preferably used by a concentration in the range from more than 0 to less than 0.5 wt. %, preferably less than 0.1 wt. %, more preferably less than 0.05 wt. %.

Preferably, the formulation comprises from one to five conductive additives, more preferably one, two, or three conductive additives, more preferably still one conductive additive.

The conductivity of the formulation of the present invention is preferably from 10⁻⁴ S/m to 10⁻¹⁰ S/m, more preferably from 10⁻⁵ S/m to 10⁻⁹ S/m, more preferably from 2*10⁻⁶ S/m to 10⁻⁹ S/m, more preferably from 10⁻⁷ S/m to 10⁻⁸ S/m.

Unless otherwise indicated, the conductivity is determined by means of a parameter analyzer. The sample to be tested is placed in a cell of known dimensions. A cell constant is determined from these dimensions. The analyzer is then used to record the current flowing when the voltage is varied from −1 V to 1 V or from 0 V to 2 V, according to cases. The data recorded for a standard solution are ohmic. In this case, the resistance may be learnt by taking the gradient of the ohmic line. Dividing the resistance by the cell constant provides the resistivity, the inverse of which is conductivity.

Solvent(s)

The solvent contained in the formulation of the present disclosure may be one or a plurality of non-aqueous solvents. Preferably, the solvent is an organic solvent or a mixture of two or more than two organic solvents. The solvent used in the ink composition is preferably a solvent capable of uniformly dissolving or dispersing solid components in the ink composition.

Examples of solvents comprise chlorinated solvents such as chloroform, methylene chloride, 1,2-dichloroethane, 1,1,2-trichloroethane, chlorobenzene, and o-dichlorobenzene, ether-based solvents such as tetrahydrofuran, methyltetrahydrofuran, dimethyltetrahydrofuran, dioxane, and anisole, aromatic hydrocarbon solvents such as toluene, o-xylene, m-xylene, p-xylene, benzaldehyde, tetralin (1,2,3,4-tetrahydronaphthalene), and 1,3-dimethoxybenzene, aliphatic hydrocarbon solvents such as cyclohexane, methylcyclohexane, trimethylcyclohexane, n-pentane, n-hexane, n-heptane, n-octane, n-nonane, and n-decane, ketone solvents such as acetone, methylethylketone, cyclohexanone, methylhexanone, benzophenone, and acetophenone, ester solvents such as ethyl acetate, butyl acetate, cellosolve ethyl acetate, methyl benzoate, benzyl phenyl acetate, and phenyl acetate, polyhydric alcohols and their derivatives such as ethylene glycol, monobutyl ether ethylene glycol, monoethyl ether ethylene glycol, monomethyl ether ethylene glycol, dimethoxyethane, propylene glycol, diethoxymethane, triethyleneglycol monoethylether, glycerol, and 1,2-hexanediol, alcohol solvents such as methanol, ethanol, propanol, isopropanol, and cyclohexanol, sulfoxide solvents such as dimethylsulfoxide, and amide solvents such as N-methyl-2-pyrolidone, and N, N-dimethylformamide.

These solvents may be used alone or in combination of two or more. The concentration of the p-type semiconductor material and of the n-type semiconductor material in the formulation is in the range from 0.1 wt. % to 10 wt. %.

Among these, aromatic hydrocarbon solvents, ether solvents, aliphatic hydrocarbon solvents, ester solvents, and ketone solvents are preferred, since this provides a good solubility, viscosity characteristics, and a uniformity during the forming of the film of the formulation. In particular, toluene, o-xylene, p-xylene, m-xylene, ethylbenzene, diethylbenzene, trimethylbenzene, n-propylbenzene, isopropylbenzene, sec-butylbenzene, n-hexylbenzene, cyclohexybenzene, benzyl benzoate, 1-methylnaphthalene, tetralin, anisole, ethoxybenzene, dimethoxybenzene, cyclohexane, dicyclohexyl, cyclohexenycylohexanone, n-heptylcyclohexane, n-hexylcyclohexane, decalin, methyl benzoate, cyclohexanone, 2-propylcyclohexanone, 2-heptanone, 3-heptanone, 4-heptanone, 2-octanone, 2-nonanone, 2-decanone, dicyclohexyl cenone, acetophenone, and benzophenone are preferred.

Two solvents or more are preferably used in combination, two or three solvents are preferably used in combination, and two solvents are particularly preferably used in combination, since the film-forming properties and the characteristics of the device are improved.

When two solvents are combined, the first solvent, also called main solvent, preferably has a boiling point between 140° C. and 200° C., and the second solvent, also called co-solvent, has a boiling point preferably equal to or higher than 180° C., even better higher than or equal to 200° C., since good film—forming properties are obtained. The two solvents preferably dissolve 1 wt. % or more of an aromatic polymer at 60° C. and in particular one of the two solvents preferably dissolves 1 wt. % or more of an aromatic polymer at 25° C., since a good viscosity is obtained.

The first solvent is then preferably toluene, o-xylene, m-xylene, p-xylene, trimethylbenzene, tetralin, anisole, alkylanisoles, naphthalene, tetrahydronaphthalene, alkylnaphthalene, or a mixture of at least two of these solvents. The second solvent is preferably acetophenone, dimethoxybenzene, benzyl benzoate, alkylnaphthalene, or a mixture of at least two of these solvents.

Further, when two solvents or more are combined, the proportion of the solvent having the highest boiling point among the combined solvents is preferably from 1 wt. % to 30 wt. %, more preferably from 2 wt. % to 20 wt. %, more preferably still from 2 wt. % to 15 wt. % with respect to the total weight of the solvents, since good viscosity and film-forming properties are obtained.

The concentration of the p-type organic semiconductor material is in the range from 4 mg/mL to 25 mg/mL per mL of solvent. The concentration of the p-type organic semiconductor material is smaller than 10 wt. % of the solution. The proportion between the p-type organic semiconductor material and the n-type organic semiconductor material varies from 1:1 to 1:2 by weight.

In the case where a volatile additive is used, the solvent should be selected to be evaporated from the semiconductor layer comprising the semiconductor materials deposited at the same time as the additive, preferably during the same processing step. The treatment temperature used to remove the solvent and the volatile additive should be selected to avoid damaging the semiconductor layer. Preferably, the deposition treatment temperature is between room temperature and 135° C. and more preferably between 60° C. and 110° C.

Manufacturing Method

The present disclosure further concerns a method of preparation of a layer comprising a p-type organic semiconductor material and an n-type organic material such as defined hereabove.

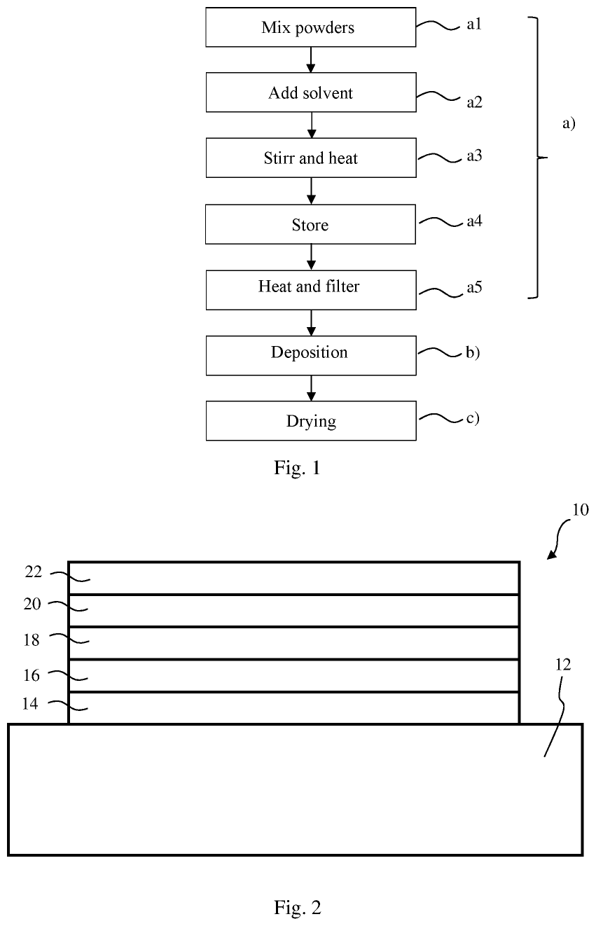

FIG. 1 illustrates in the form of a block diagram an embodiment of a method of manufacturing such a layer.

Said method comprising the steps of a) providing a formulation comprising a p-type organic semiconductor material, an n-type organic material, at least one solvent, and possibly additives, b) depositing the formulation on a substrate, and c) essentially removing the solvent.

Preferably, step b) of the present method is carried out by spin coating or by spreading. Step c) may be carried out by heating the formulation once deposited, by placing the formulation in an enclosure at a sub-atmospheric pressure to perform a vacuum evaporation, or by combining heating and vacuum evaporation. Steps b) and c) may be at least partially confounded. When the solvent comprises a first solvent and a second solvent such as previously described, the heating temperature at step c) may be higher than the boiling temperature of the first solvent and lower than the boiling temperature of the second solvent. As a variant, when the solvent comprises a first solvent and a second solvent such as previously described, the heating temperature at step c) may be lower than the boiling temperature of the first solvent and than the boiling temperature of the second solvent. The first solvent, having the lowest boiling temperature, will however evaporate faster than the second solvent. Step c) may be carried out at the atmospheric pressure or under vacuum.

In the context of the present application, the expression “essentially eliminating the solvent” is used to indicate that at least 50 wt. %, preferably at least 60 wt. % or 70 wt. %, more preferably at least 80 wt. %, or 90 wt. %, more preferably still at least 92 wt. %, or 94 wt. %, or 96 wt. %, or 98 wt. %, particularly at least 99 wt. %, or at least 99.5 wt. % of the solvent are removed, the percentage by weight being with respect to the weight of the solvent in the formulation provided at step a).

The formulation used preferably has a viscosity at 20° C. of at least 1 mPa·s. Preferably, the solution has a viscosity at 20° C. of at most 100 mPa·s, more preferably of at most 50 mPa·s, and more preferably still of at most 30 mPa·s. For a spin coating or deposition by spreading, the solution used preferably has a viscosity in the range from 4 cPo (4 mPa·s) to 15 cPo (15 mPa·s).

According to an embodiment, the temperature of preparation of the formulation, particularly at step a), is in the range from 20° C. to 90° C., preferably from 50° C. to 70° C.

According to an embodiment, step a) of preparation of the formulation comprises mixing powders corresponding to the p-type organic semiconductor material, to the n-type organic semiconductor material, and possibly to additives (step a1), adding a solvent (step a2), and stirring and heating (step a3).

Step a1 may be carried out by mixing a powder of the p-type organic semiconductor material and a powder of the n-type organic semiconductor material.

At step a1, the p-type organic semiconductor material is a polymer characterized by a targeted molecular weight and is obtained by mixing the polymer, for example, in the form of a powder, with a first molecular weight greater than the targeted molecular weight and the same polymer, for example, in the form of a powder, with a second molecular weight smaller than the targeted molecular weight. This enables to reproducibly obtain the solution with the desired viscosity.

According to an embodiment, step a3 comprises heating the formulation for from 3 hrs to 24 hrs, preferably from 6 hrs to 15 hrs.

The mixtures and formulations of polymers according to the present invention may further comprise one or a plurality of other components or additives selected, for example, among surface-active compounds, lubricant agents, hydrophobic agents, adhesive agents, flow improvement agents, antifoam agents, de-aerator agents, reactive or non-reactive diluents, dyes, pigments, stabilizers, nanoparticles, or inhibitors.

Step a) of manufacturing the formulation may comprise the storage (step a4) of the formulation obtained at step a3.

When the formulation has to be stored before step b), manufacturing step a) further comprises a step a5 of heating the formulation prior to step b), for example, from 30 min to 2 hrs, at a temperature in the range from 50° C. to 70° C., possibly with a stirring, followed by a filtering step. The filtering step is preferably implemented after the heating step. The filtering step may be implemented by having the formulation pass through a filter. The filter may be based on cellulose acetate, polytetrafluoroethylene (PFTE), poly(vinylidene fluoride) (PVDF), regenerated cellulose, or glass fibers. The pore size of the filter may be in the range from 0.2 μm to 1 μm, preferably equal to approximately 0.45 μm.

Electronic Device

Generally, the present application also concerns an optoelectronic device comprising a layer which comprises a p-type organic semiconductor material and an n-type semiconductor material such as previously defined. The preferred devices are OPDs, OLEDs, and OPVs.

The particularly preferred electronic devices are OPD, OLED, and OPV devices, in particular bulk heterojunction OPD devices (BHJ).

The present OPV or OPD device may preferably comprise, between the active layer and the first or the second electrode, one or a plurality of additional buffer layers used as hole transport layers and/or electron blocking layers, which comprise a material such as a metal oxide, such as for example, ZTO, MoOₓ, NiOₓ a conjugated polymer electrolyte, such as for example, PEDOT:PSS, a conjugated polymer, such as for example polytriarylamine (PTAA), an organic compound, such as for example N,N′-diphenyl-N,N′-Bis (1-naphtyl) (1,1′-biphenyl)-4,4′-diamine (NPB), N,NT-diphenyl-N,N′-(3-methylphenyl)-1,1T-biphenyl-4,4T-diamine (TPD), or as hole blocking layers and/or electron transport layers, comprising a material such as a metal oxide, such as for example ZnOₓ, TiOₓ, a salt, such as for example, LiF, NaF, CsF, a conjugated polymer electrolyte, such as for example poly[3-(6-trimethylammoniumhexyl)thiophene], poly(9,9-bis (2-ethylhexyl)-fluorene]-b-poly[3-(6-trimethylammoniumhexyl) thiophene], or poly(9,9-bis(3″-(N,N-dimethylamino)propyl)-2,7-fluorene)-alt-2,7-(9,9-dioctylfluorene)] or an organic compound, such as for example tris(8-quinolinolato)-aluminum (III) (Alq₃), 4,7-diphenyl-1,10-phenanthroline, polyethylenimine (PEI), and poly(ethylenimine) ethoxyl.

In a mixture of a polymer according to the present invention with a fullerene or a modified fullerene, the polymer:fullerene ratio is from 1:1 to 1:2 by weight. A polymer binder may also be included, from 5 wt. % to 95 wt. %. Examples of binder comprise polystyrene (PS), polypropylene (PP), and polymethylmethacrylate (PMMA).

FIG. 2 is a partial simplified cross-section view of a first embodiment of an OPD device 10. Device 10 comprises the following layers (in the order from bottom to top):
possibly a substrate 12;
an electrode 14 with a high work function, preferably comprising a metal oxide, such as for example ITO, used as an anode;
possibly, a conductive polymer layer 16 or hole transport layer, preferably comprising an organic polymer or a mixture of polymers, for example, PEDOT:PSS (poly(3,4-ethylenedioxythiophene): poly(styrene-sulfonate)) or TBD (N,N′-dyphenyl-N—N′-bis(3-methylphenyl)-1,1′biphenyl-4,4′-diamine) or NBD (N,N′-dyphenyl-N—N′Bis(1-naphthylphenyl)-1,1′biphenyl-4,4′-diamine);
a layer 18, also called “active layer”, comprising a p-type and n-type organic semiconductor, capable of existing for example in the form of a p-type/n-type bilayer or in the form of distinct p-type and n-type layers, or in the form of a mixture or of p-type and n-type semiconductor, forming a BHJ;
possibly, a layer 20 having electron transport properties, for example comprising LiF; and
an electrode 22 with a low work function, preferably comprising a metal such as for example aluminum, used as a cathode,
   where at least one of the electrodes, preferably the anode, is transparent to visible light.

A second embodiment corresponding to a preferred OPD device according to the invention is an inverted OPD and comprises the following layers (from bottom to top):
possibly a substrate;
a metal or metal oxide electrode with a high work function, for example, comprising ITO, used as a cathode;
a layer having hole blocking properties, preferably comprising a metal oxide such as TiOₓ, ZnOₓ, PEI, PEIE;
an active layer comprising a p-type and n-type organic semiconductor, located between the electrodes, capable of existing for example in the form of a p-type/n-type bilayer or in the form of distinct p-type and n-type layers, or in the form of a mixture or of p-type and n-type semiconductor, forming a BHJ;
possibly, a conductive polymer layer or a hole transport layer, preferably comprising an organic polymer or a mixture of polymers, for example, PEDOT:PSS, or TBD, or NBD; and
an electrode comprising a metal with a high work function such as, for example, silver, used as an anode,
   where at least one of the electrodes, preferably the cathode, is transparent to visible light.

As a variant, the materials according to the invention may be used in OLEDs, for example, as an active display material in flat display applications, or as a backlighting of a flat display, such as for example, a liquid crystal display. Current OLEDs are formed by means of multilayer structures. An emission layer is generally sandwiched between one or a plurality of electron transport and/or hole transport layers. By applying an electric voltage, electrons and holes, as charge carriers, displace towards the emission layer where their recombination results in the excitation and thus in the luminescence of the luminophore units contained in the emission layer. The compounds, materials, and films of the invention may be used in the emission layer, corresponding to their electric and/or optical properties. Further, their use in the emission layer is particularly advantageous if the compounds, materials, and films according to the invention themselves have light-emitting properties or comprise light-emitting groups or compounds.

The selection, the characterization, as well as the treatment of compounds or of monomer, oligomer, and polymer materials adapted for a use in OLEDs are generally known by those skilled in the art, see for example Müller et al., Synth. Metals, 2000, 111-112, 31-34, Alcala, J. Appl. Phys., 2000, 88, 7124-7128 and the literature cited in this publication.

According to another use, the materials according to this invention, in particular those having photoluminescent properties, may be used as materials of light sources, for example, in display devices, such as described in documents EP 0 889 350 or by C. Weder et al., Science, 1998, 279, 835-837.

Formulations have been obtained. For all these formulations, a p-type polymer, capable of comprising thiophene and aryl structural units and such as described in U.S. Pat. No. 9,601,695, has been used.

### Example 1

A first solution has been implemented. A powder of the p-type polymer has been mixed with a PC₆₀BM powder. First and second solvents have been added to the powder mixture. The first solvent was o-xylene. The proportion of the first solvent was 97 wt. % with respect to the total weight of the first and second solvents. The second solvent was acetophenone. The proportion of the second solvent was 3 wt. % with respect to the total weight of the first and second solvents. The concentration of the polymer in the solution was approximately 6 g/L. The concentration of PC₆₀BM in the solution was approximately 12 g/L. The viscosity of the first solution has been measured and was equal to approximately 5 cPo. A layer of the first solution has been deposited by coating.

### Example 2

A second solution has been implemented. A powder of the p-type polymer has been mixed with a PC₆₀BM powder. A solvent has been added to the powder mixture. The solvent was 1,2,3,4-tetrahydronaphthalene. The concentration of the polymer in the solution was approximately 10 g/L. The concentration of PC₆₀BM in the solution was approximately g/L. The viscosity of the second solution has been measured and was equal to approximately 10 cP. A layer of the second solution has been deposited by coating.

### Example 3

A third solution has been implemented. A powder of the p-type polymer has been mixed with a PC₆₀BM powder. First and second solvents have been added to the powder mixture. The first solvent was 1,2,4-trimethylbenzene. The proportion of the first solvent was 90 wt. % with respect to the total weight of the first and second solvents. The second solvent was 1,3-dimethoxybenzene. The proportion of the second solvent was 10 wt. % with respect to the total weight of the first and second solvents. The concentration of the polymer in the solution was approximately 15 g/L.

The concentration of PC₆₀BM in the solution was approximately 26.25 g/L. The viscosity of the first solution has been measured and was equal to approximately 8 cPo (8 mPa·s). A layer of the first solution has been deposited by spin coating.

Various embodiments and variants have been described. Those skilled in the art will understand that certain features of these embodiments can be combined and other variants will readily occur to those skilled in the art. Finally, the practical implementation of the embodiments and variants described herein is within the capabilities of those skilled in the art based on the functional indications provided hereinabove.

1. A formulation comprising:
a p-type organic semiconductor polymer comprising a conjugated aryl compound, a conjugated heteroaryl compound, or a mixture of at least two of these compounds;
an n-type semiconductor material comprising fullerene, substituted fullerene, or a mixture of at least two of these compounds; and
a non-aqueous solvent, the concentration of the p-type organic semiconductor polymer being in the range from 8 mg/mL to 12 mg/mL per milliliter of solvent and the concentration of the n-type organic semiconductor material being in the range from 18 mg/mL to 22 mg/mL per milliliter of solvent,
wherein the solvent comprises toluene, o-xylene, m-xylene, or p-xylene, trimethylbenzene, tetralin, anisole, alkylanisoles, naphtalene,
tetrahydronaphtalene, alkylnaphtalene, or a mixture of at least two of these solvents.

2. The formulation according to claim 1, wherein the formulation has a viscosity in the range from 8 mPa·s to 12 mPa·s.

3. The formulation according to claim 1, wherein the p-type semiconductor polymer comprises aryl groups and thiophene groups.

4. The formulation according to claim 1, wherein the n-type semiconductor material is PCBM-C₆₀.

5. The formulation according to claim 1, wherein the solvent is tetrahydronaphthalene.

6. A use of the formulation according to claim 1, as a coating or printing ink for the preparation of optoelectronic devices.

7. A method of preparing the formulation according to claim 1, comprising the steps of: mixing the p-type organic semiconductor polymer and the n-type semiconductor material in the form of powders, adding the non-aqueous solvent to the mixture to obtain the formulation, heating the formulation, and filtering the formulation.

8. The method according to claim 7, wherein the p-type organic semiconductor polymer has a targeted molecular weight and is obtained by mixing a first powder of the polymer having a first molecular weight greater than the targeted molecular weight and a second powder of the same polymer having a second molecular weight smaller than the targeted molecular weight.

9. The method according to claim 7, wherein the step of heating the formulation comprises heating the formulation for from 30 min to 2 hrs at a temperature in the range from 50° C. to 70° C.

10. The method according to claim 7, wherein the filtering step is implemented by having the formulation pass through a filter having a pore size in the range from 0.2 μm to 1 μm.

11. An optoelectronic device prepared from the formulation according to claim 1.

12. The optoelectronic device according to claim 11, wherein the device is selected from among organic photodiodes, organic light-emitting photodiodes, and organic photovoltaic cells.
